(19) United States
(12) Patent Application Publication
(10) Pub. No.: US 2023/0408326 A1
(43) Pub. Date: Dec. 21, 2023

(54) Non-Contact Vibration Testing System for Enhanced Component Placement

(71) Applicant: Google LLC, Mountain View, CA (US)

(72) Inventors: Jianmin Zhang, Los Gatos, CA (US); Mingfeng Xue, Mountain View, CA (US); Shengyin Ding, Cupertino, CA (US)

(73) Assignee: Google LLC, Mountain View, CA (US)

(21) Appl. No.: 18/457,088

(22) Filed: Aug. 28, 2023

Related U.S. Application Data
(60) Provisional application No. 63/578,814, filed on Aug. 25, 2023.

(51) Int. Cl. G01H 9/00; G01R 15/20; G01R 19/00

(52) U.S. Cl. CPC G01H 9/00; G01R 19/0092; G01R 15/20

(57) ABSTRACT

This document describes systems and techniques for a non-contact vibration testing system for enhanced component placement. In one example a testing system includes a mounting device configured to receive an electronic device having a magnetic-field-sensitive component, the magnetic-field-sensitive component configured to vibrate in response to a variable-frequency magnetic field. A magnetic coil is configured to generate the variable frequency magnetic field in response to receiving an alternating electric current. The magnetic coil is disposed proximate to the mounting device to cause the variable-frequency magnetic field to propagate into a region of the mounting device in which the electronic device is configured to be received. The variable-frequency magnetic field configured to cause the magnetic-field-sensitive component to vibrate.

### CROSS-REFERENCE TO RELATED APPLICATION(S)

This application claims priority to U.S. Provisional Patent Application 63/578,814, filed on Aug. 25, 2023, which is incorporated herein by reference in its entirety.

### SUMMARY

This document describes systems and techniques for a non-contact vibration testing system for enhanced component placement. In aspects, an electronic device is tested for its response to vibration induced in the electronic device without a vibrating mechanism physically contacting the electronic device. In one example a testing system includes a mounting device configured to receive an electronic device having a magnetic-field-sensitive component, the magnetic-field-sensitive component configured to vibrate in response to a variable-frequency magnetic field. A magnetic coil is configured to generate the variable frequency magnetic field in response to receiving an alternating electric current. The magnetic coil is disposed proximate to the mounting device to cause the variable-frequency magnetic field to propagate into a region of the mounting device in which the electronic device is configured to be received. The variable-frequency magnetic field configured to cause the magnetic-field-sensitive component to vibrate.

This Summary is provided to introduce systems and techniques for testing an electronic device for its response to vibration induced in the electronic device without a vibrating mechanism physically contacting the electronic device as further described below in the Detailed Description and Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of systems and techniques for testing an electronic device for its response to vibration induced in the electronic device without a vibrating mechanism physically contacting the electronic device are described in this document with reference to the following drawings. The same numbers are used throughout the drawings to reference like features and components:

FIG. 1 is a schematic diagram of an example testing system configured to monitor response of an electronic device to non-contact vibration testing;

FIGS. 2A and 2B are schematic diagrams depicting a variable magnetic force being induced in an example magnetic-field-sensitive component to vibrate as a result of a change in an electric current applied to a magnetic coil;

FIGS. 3A-3D are perspective views of an electronic device undergoing magnetically-induced vibration tests as a result of the magnetic-field-sensitive component being coupled to the electronic device or a component of the electronic device at different locations;

FIGS. 4A and 4B are perspective views of an electronic device to which multiple magnetic-field-sensitive components have been coupled to multiple locations on the electronic device or to multiple components of the electronic device at different locations; and

FIG. 5 is a flow diagram of an example method of subjecting an electronic device to vibration without a vibrating mechanism physically contacting the electronic device.

### DETAILED DESCRIPTION

### Overview

Over time, many people are becoming increasingly dependent upon personal electronic devices such as mobile telephones and wireless earbuds. With increasing dependence on such devices for telephone calls or listening to music, users may become increasingly sensitive to spurious noise generated by such devices.

For example, any alternating or varying current signal passing through a capacitor may, at various frequencies of the current, generate sounds and vibrations that are discernable to a user. Inductors or other components also may generate undesired sounds and vibrations.

Some unwanted sound may be avoided by changing the positioning of such components in/on an electronic device, such as by changing the orientation or positioning of these components on a printed circuit board. However, it may be difficult to replicate in a design laboratory how simulated use of a device may generate unwanted sounds and vibrations. Operating the devices in an attempt to stimulate vibration may not fully or accurately generate the types of unwanted sounds or vibrations that may be encountered by users of the electronic device. Similarly, mechanically stimulating vibrations by physically engaging a vibrating mechanism with the electronic device may not replicate the types of vibration of the electronic device that may occur during use of the electronic device.

To this end, this document describes systems and techniques for a non-contact vibration testing system for enhanced component placement. The systems and techniques for testing an electronic device for its response to vibration induced in the electronic device without a vibrating mechanism physically contacting the electronic device. In aspects, an electronic device is tested for its response to vibration induced in the electronic device without a vibrating mechanism physically contacting the electronic device. In one example a testing system includes a mounting device configured to receive an electronic device having a magnetic-field-sensitive component, the magnetic-field-sensitive component configured to vibrate in response to a variable-frequency magnetic field. A magnetic coil is configured to generate the variable frequency magnetic field in response to receiving an alternating electric current. The magnetic coil is disposed proximate to the mounting device to cause the variable-frequency magnetic field to propagate into a region of the mounting device in which the electronic device is configured to be received. The variable-frequency magnetic field configured to cause the magnetic-field-sensitive component to vibrate.

### Example Systems

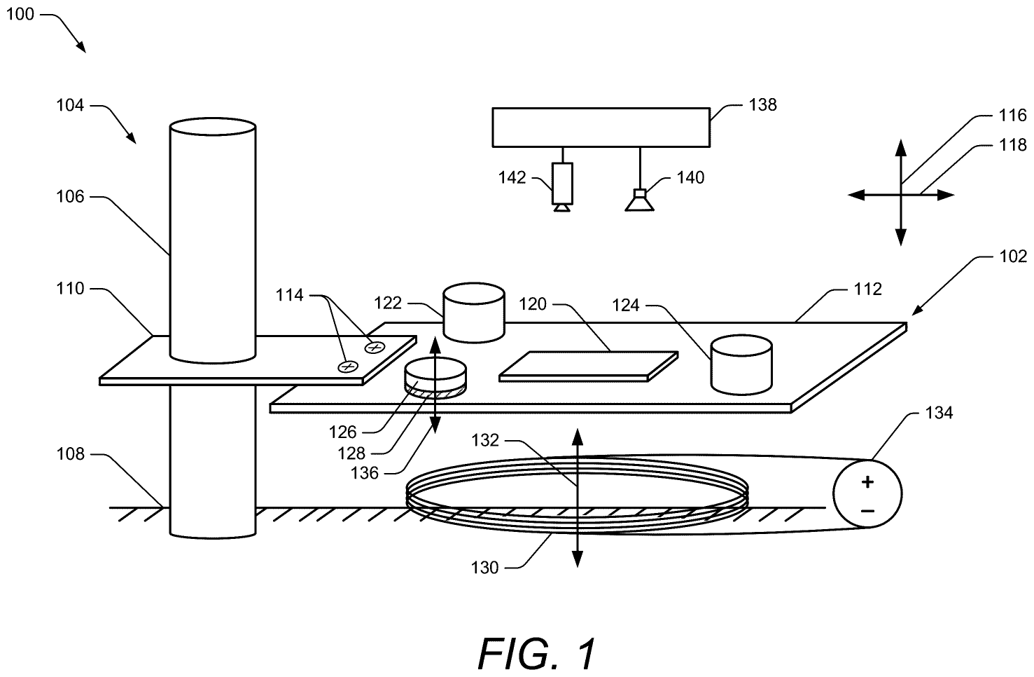

FIG. 1 illustrates an example testing system 100 configured to test response of an electronic device 102 to non-contact vibration testing. The system 100 may include one or more mounting devices, such as mounting device 104. In aspects, the mounting device 104 can include a support 106 that is configured to be anchored to or to rest upon a surface 108 or some other base. The mounting device 104 may further include a clamp 110 that is configured to securably receive the electronic device 102. For purposes of illustration, the electronic device 102 includes a printed circuit board 112, but the electronic device 102 can include any of a variety of electronic hardware, including, but not limited to, an electronics module, a smartphone, a hearable device, a system-on-a-chip, a standalone electronic component, and so on. The electronic device 102 may be secured to the clamp via set screws 114 or another clamping mechanism, such as a vise, spring-loaded clamps, etc. The mounting device 104 may be configured to secure the electronic device 102 in a vertical dimension 116 and a horizontal dimension 118 relative to the surface 108 so that the electronic device 102 does not rotate or translate in the vertical dimension 116 or the horizontal dimension 118 as a result of vibrations induced in the electronic device 102 as described below.

The electronic device 102 may include one or more integrated circuits 120 and one or more additional components 122 and 124, such as capacitors, inductors, or other electronic components. When the electronic device 102 is in the nature of a printed circuit board 112, the printed circuit board 112 may include conductive traces (not shown) configured to electrically couple the components 120, 122, and 124 to each other or to other components. As previously described, an alternating or varying current flowing through the components 122 and 124 during use of the electronic device 102 may cause the components 122 and 124 to vibrate and, in turn, may cause the electronic device 102 to vibrate. It is an object of the system 100 to facilitate monitoring of how configuration and/or placement of the components 122 and 124 may affect these vibrations and whether changing the configuration and/or placement of the components 122 and 124 may change, reduce, or eliminate vibration.

One or more magnetic-field-sensitive components 126 may be secured to the electronic device 102 with an adhesive 128, such as a permanent or a detachable adhesive. The magnetic-field-sensitive component 126 may include a permanent magnet or another object that has become magnetized or otherwise generates a magnetic field. Use of a detachable adhesive may simplify movement of the magnetic-field-sensitive component 126 to different locations on the electronic device 102 to test different configurations of the electronic device 102. A detachable adhesive allows the magnetic-field-sensitive component 126 to be detached from a first location on the electronic device 102 and reattached to a second location on the electronic device 102, as described further below. On the other hand, a permanent adhesive may provide a more rigid bond between the magnetic-field-sensitive component 126 which may enable more efficient transfer of vibration from the magnetic-field-sensitive component 126 to the electronic device 102.

A magnetic coil 130 is disposed proximate to the electronic device 102 secured by the mounting device 104. The magnetic coil 130 is configured to generate a variable frequency magnetic field 132, represented in FIG. 1 by a bidirectional arrow along an axis of the magnetic coil 130 to intersect a body of the electronic device 102 in response to application of an alternating or varying current. The alternating current may be applied by an alternating current source 134 electrically connected to conductors at ends of the magnetic coil 130. The alternating electric current source 134 may be configured to provide alternating current at selectable current frequencies, thus resulting in the magnetic coil 130 generating the variable frequency magnetic field 132 at different frequencies.

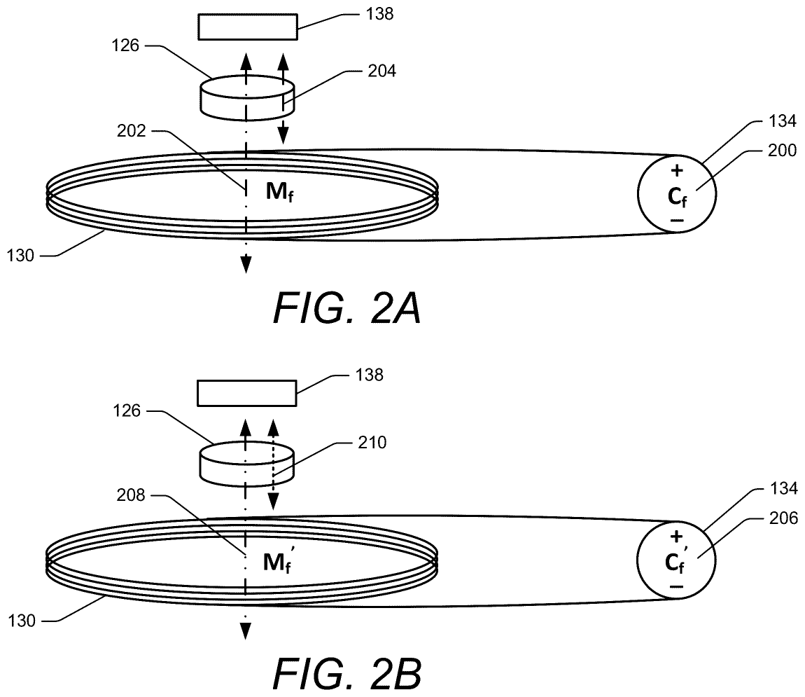

When the alternating current source 134 applies alternating current to the magnetic coil 130, the variable frequency magnetic field 132 may interact with the magnetic-field-sensitive component 126. The variable frequency magnetic field 132 interacting with the magnetic-field-sensitive component 126 causes the magnetic-field-sensitive component 126 and the electronic device 102 to which it is coupled to vibrate, as further described below with reference to FIGS. 2A and 2B.

A vibration monitoring sensor 138 can detect and monitor the vibration of the electronic device 102 resulting from the magnetic force imparted to the magnetic-field-sensitive component 126 by the variable frequency magnetic field 132 generated by magnetic coil 130. The vibration monitoring sensor 136 may include a microphone or other auditory sensor 140 to detect and measure the frequency of the vibrations. The vibration monitoring sensor 138 also may include an optical sensor 142, such as a laser-based sensor to measure the Doppler shift of reflected energy to detect and measure vibration of the electronic device 102.

FIGS. 2A and 2B depicts how varying or otherwise modulating a frequency of the alternating current generated by the alternating current source 134 affects vibration of the magnetic-field-sensitive component 126 and, by extension, the electronic device 102. Referring to FIG. 2A, the alternating current source 134 supplying an alternating current C_{f} 200 to the magnetic coil 130, the magnetic coil 130 generates an alternating magnetic field M_{f} 202 (represented by a dotted and dashed line in FIG. 2A) that intersects the body of the electronic device 102 (not illustrated in FIG. 2A). The alternating magnetic field M_{f} 202 interacting with the magnetic-field-sensitive component 126 results in an alternating magnetic force 204 (represented by a dashed line in FIG. 2A) being exerted on the magnetic-field-sensitive component 126 and the electronic device 102 to which the magnetic-field-sensitive component 126 is coupled. The alternating magnetic force 204 resulting from application of the alternating current C_{f} 200 to the magnetic coil 130 thus may cause vibration of the magnetic-field-sensitive component 126 (and the device to which it is coupled) at a first frequency measurable by the vibration monitoring sensor 138.

Referring to FIG. 2B, the alternating current source 134 supplying an alternating current C_{f}′ 206 to the magnetic coil 130, the magnetic coil 130 generates an alternating magnetic field M_{f}′ 208 (represented by a double-dotted and dashed line in FIG. 2B). The alternating magnetic field M_{f}′ 208 intersects with the body of the electronic device 102 (not illustrated in FIG. 2B) and interacts with the magnetic-field-sensitive component 126, resulting in a second alternating magnetic force 210 (represented by a dotted line in FIG. 2B) being exerted on the magnetic-field-sensitive component 126 and the electronic device 102 to which the magnetic-field-sensitive component 126 is coupled. The alternating magnetic force 210 results in vibration of the magnetic-field-sensitive component 126 (and the device to which it is coupled) at a second frequency measurable by the vibration monitoring sensor 138. Thus, modulating or otherwise varying or changing the frequency of the alternating current C_{f} 200 or C_{f}′ 206 supplied by the alternating current source 134 to the magnetic coil 130 changes the variable frequency magnetic field M_{f} 202 or M_{f}′ 208, respectively, generated by the magnetic coil 130 and, thus, changes vibration induced in the magnetic-field-sensitive component 126.

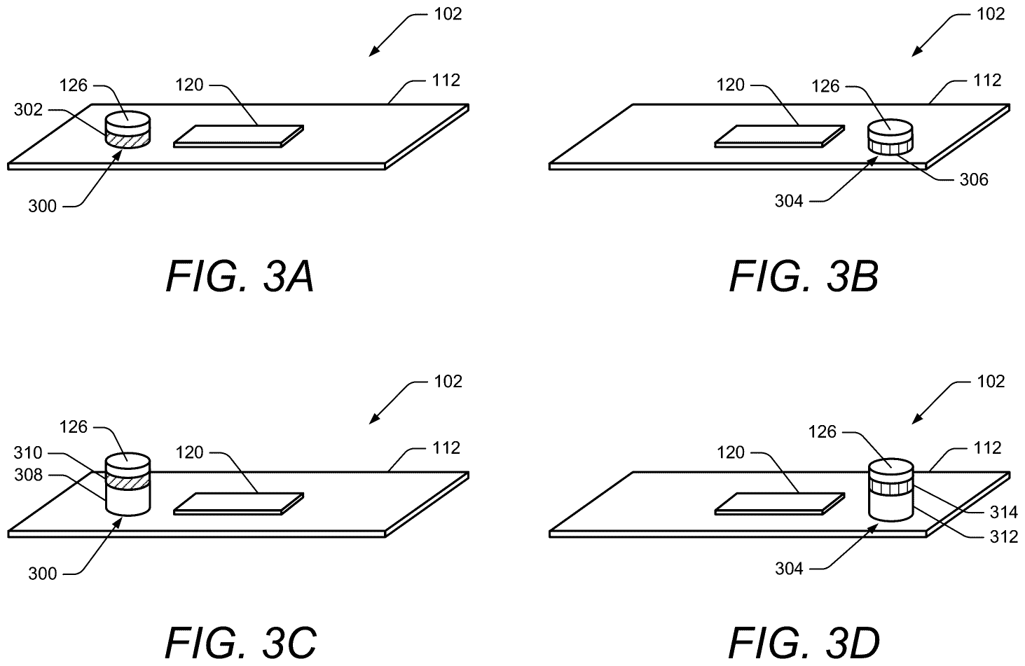

Referring to FIGS. 3A-3D, in addition to being able to monitor different levels of vibration of the electronic device 102, the system 100 (FIG. 1) may be used to measure vibration induced at different locations on the electronic device 102. It will be appreciated that a component, such as a capacitor or another component that may vibrate in response to application of an alternating current, may be situated at different locations on the printed circuit board 112 while still being electrically coupled to one or more other components and to perform the same function. However, while placement of the component may not change the function of the component, the placement of the component may affect the vibration imparted by the component to the electronic device 102. Positioning the magnetic-field-sensitive component 126 at different locations on the electronic device 102 allows for testing the vibration of the electronic device 102 as a result of these different placements.

In aspects, the magnetic-field-sensitive component 126 may be coupled directly to the printed circuit board 112 or another portion of the electronic device 102 to simulate vibration of a component (not shown in FIG. 3A) at a selected location. For example, referring to FIG. 3A, the magnetic-field-sensitive component 126 is coupled at a component location 300 on the printed circuit board 112 with an adhesive 302. Vibrations of the electronic device 102 caused by a component situated at the component location 300 may be tested by securing the electronic device 102 with the mounting device 104 and applying varying, alternating electric currents to the magnetic coil 130, as described with reference to FIGS. 1, 2A, and 2B. Referring to FIG. 3B, the magnetic-field-sensitive component 126 is coupled at a component location 304 on the printed circuit board 112 with an adhesive 306. Vibrations of the electronic device 102 caused by a component situated at the location 304 may be tested by securing the electronic device 102 with the mounting device 104 and applying varying, alternating electric currents to the magnetic coil 130, as described with reference to FIGS. 1, 2A, and 2B. Thus, without actually mounting the component on the printed circuit board 112 at selected component locations 300 and 304, vibration that may result from mounting the component at the locations 300 and 304 may be simulated. The adhesive 302 or 306 used to couple the magnetic-field-sensitive component 126 to the printed circuit board 112 at the component locations 300 or 304, respectively, may include a permanent or a detachable adhesive, as previously described.

Alternatively, instead of coupling the magnetic-field-sensitive component 126 to the printed circuit board, the magnetic-field-sensitive component 126 may be coupled to a component mounted on the printed circuit board 112. For example, referring to FIG. 3C, the magnetic-field-sensitive component 126 is coupled to a component 308 mounted at the component location 300 on the printed circuit board 112. Instead of coupling the magnetic-field-sensitive component 126 to the printed circuit board with an adhesive 302, as described with reference to FIG. 3A, the magnetic-field-sensitive component 126 is coupled to the component 308 with an adhesive 310. Vibrations of the electronic device 102 caused by the component 308 situated at the location 300 thus may be tested by securing the electronic device 102 with the mounting device 104 and applying alternating electric currents to the magnetic coil 130, as described with reference to FIGS. 1, 2A, and 2B. Referring to FIG. 3D, the magnetic-field-sensitive component 126 is coupled to a component 312 mounted at the component location 304 on the printed circuit board 112 by coupling the magnetic-field-sensitive component 126 to the component 312 with an adhesive 314. As with the examples of coupling the magnetic-field-sensitive component 126 to the printed circuit board 112 as described with reference to FIGS. 3A and 3B, the adhesive 310 or 314 used to couple the magnetic-field-sensitive component 126 to the components 308 or 312, respectively, may include a permanent or a detachable adhesive.

In implementations, the vibration that may result from use of a particular component may be simulated by coupling the magnetic-field-sensitive component 126 to the printed circuit board 112 or by coupling the magnetic-field-sensitive component 126 to the component 308 or 312 mounted on the printed circuit board 112. As a result, different designs or potential designs or configurations of the electronic device 102 may be tested for vibrations that may result from placement of one or more components. The magnetic-field-sensitive component 126 may be coupled to the printed circuit 112 at one or more locations to simulate vibrations that may result from the component being situated at those locations; when a component is mounted on the printed circuit board 112 at a component location, the magnetic-field-sensitive component 126 may be coupled to the component to simulate vibrations resulting from that design choice. In any case, the vibrations resulting from a component at the selected location may be simulated without applying a current to the component—or without the component actually being mounted on the printed circuit board 112—and without a vibrating mechanism physically contacting the printed circuit board 112 by using the magnetic coil 130 to impart a variable frequency magnetic field that intersects a body of the electronic device 102.

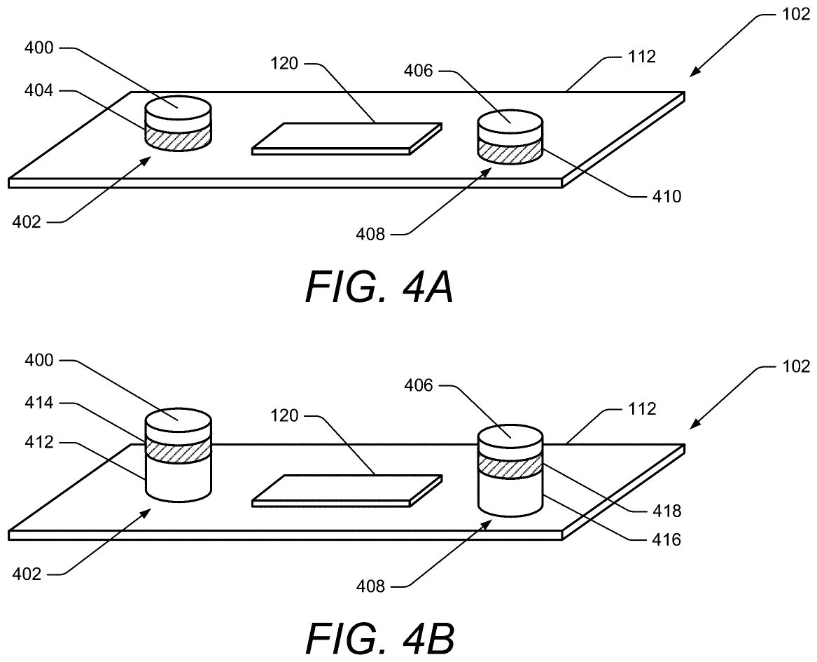

Referring to FIGS. 4A and 4B, the system 100 (FIG. 1) may also be used to test vibrations that may result from multiple components on an electronic device 102. Referring to FIG. 4A, analogous to the examples of FIGS. 3A and 3B, a first magnetic-field-sensitive component 400 may be coupled to the printed circuit board 112 at a first component location 402 with an adhesive 404 and a second magnetic-field-sensitive component 406 may be coupled to the printed circuit board 112 at a second component location 408 with an adhesive 410. Vibrations that may result from components being installed at the locations 402 and 408 may be simulated by using the magnetic coil 130 (see FIGS. 1, 2A, and 2B) to impart magnetic force to the magnetic-field-sensitive components 400 and 406.

Referring to FIG. 4B, analogous to the examples of FIGS. 3C and 3D, the first magnetic-field-sensitive component 400 may be coupled to a first component 412 coupled to the printed circuit board 112 at the first component location 402 with an adhesive 414 and the second magnetic-field-sensitive component 406 may be coupled to a second component 416 coupled to the printed circuit board 112 at the second component location 408 with an adhesive 418. Vibrations that may result from the components 412 and 416 installed at the component locations 402 and 408 may be simulated by using the magnetic coil 130 (see FIGS. 1, 2A, and 2B) to impart magnetic force to the magnetic-field-sensitive components 400 and 406.

Thus, in aspects described with reference to FIGS. 3A-3D, vibrations resulting from a single component positioned at a single component location may be tested, while in aspects described with reference to FIGS. 4A and 4B, vibrations resulting from multiple components at multiple locations may be tested. In both types of cases, the vibrations resulting from placement of components may be tested by applying an alternating electric current to the magnetic coil 130 (see FIGS. 1, 2A, and 2B) to impart magnetic force to the magnetic-field-sensitive components without having to apply current to the components themselves—or without the components actually being installed—and without a vibrating mechanism physically contacting the electronic device 102.

### Example Method

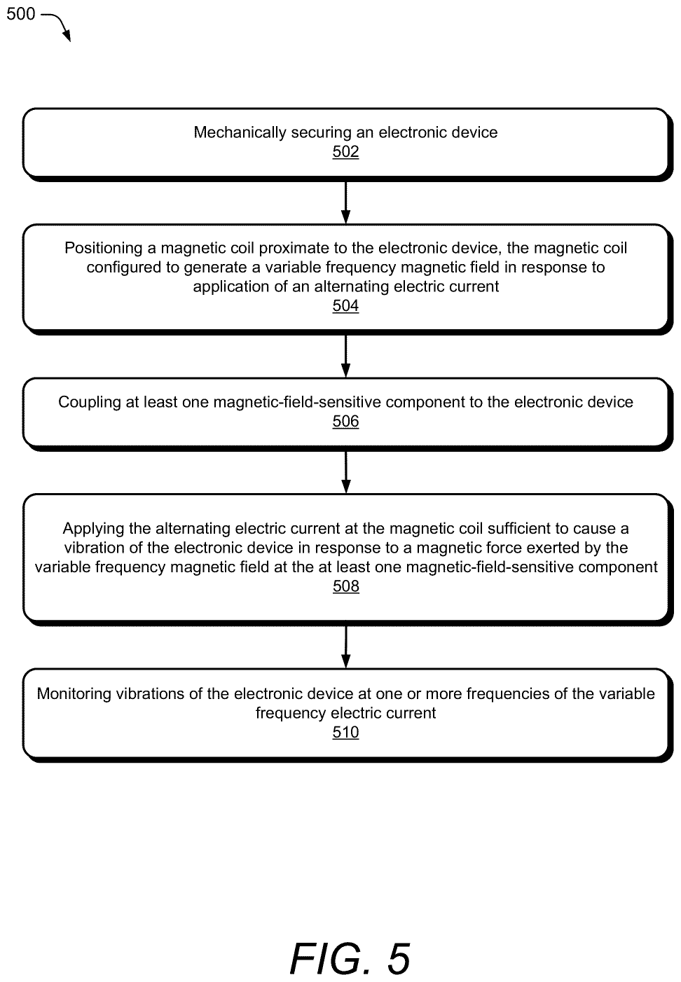

FIG. 5 is a flow diagram of an example method for performing magnetically-induced vibration testing of a configuration of an electronic device as previously described with reference to FIGS. 1-4B. At a block 502, an electronic device 102 is mechanically secured. For example, the electronic device 102 may be mechanically secured in one or more dimensions (e.g., vertically, horizontally), such as by using the mounting device 104. At a block 504, a magnetic coil 130 is positioned proximate to the electronic device 102. The magnetic coil 130 may be configured to generate a variable frequency magnetic field 132 in response to application of an alternating electric current as described with reference to FIGS. 1, 2A, and 2B. At a block 506, at least one magnetic-fielding producing component is coupled to the electronic device 102 as described with reference to FIGS. 1-4B. At a block 508, an alternating electric current is applied to the magnetic coil 130 sufficient to cause a vibration of the electronic device 102 in response to a magnetic force 204 or 210 exerted by the variable frequency magnetic field 202 or 208, respectively (see FIG. 2), at the at least one magnetic-field-sensitive component 126. At a block 510, vibrations of the electronic device 102 are monitored at one or more frequencies of the variable frequency electric current, such as by using the vibration monitoring sensor 138 described with reference to FIGS. 1, 2A, and 2B.

The preceding discussion describes systems and techniques for testing an electronic device for its response to vibration induced in the electronic device without a vibrating mechanism physically contacting the electronic device. Through these systems and techniques, various configurations of an electronic device may be tested to measure vibration resulting from the various configurations. These systems and techniques may be realized using one or more of the entities or components shown in FIGS. 1-4B and used as described with reference to FIG. 5. However, the figures illustrate only some of the many possible systems capable of employing the described techniques. Moreover, although systems and techniques are described herein as being non-contact, it will be understood by those skilled in the art that the vibration testing system may additionally utilize apparatuses that physically contact an electronic device to induce vibrations.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although implementations of systems and techniques for a non-contact vibration testing system for enhanced component placement have been described in language specific to certain features and/or methods, the subject of the appended claims is not necessarily limited to the specific features or methods described. Rather, the specific features and methods are disclosed as example implementations of systems and techniques for a non-contact vibration testing system for enhanced component placement.

What is claimed is:

1. A testing system comprising:
a mounting device configured to receive an electronic device having a magnetic-field-sensitive component, the magnetic-field-sensitive component configured to vibrate in response to a variable-frequency magnetic field; and
a magnetic coil configured to generate the variable-frequency magnetic field in response to receiving an alternating current, the magnetic coil disposed proximate to the mounting device to cause the variable-frequency magnetic field to propagate into a region of the mounting device in which the electronic device is configured to be received, the variable-frequency magnetic field configured to cause the magnetic-field-sensitive component to vibrate.

2. The testing system of claim 1, wherein the magnetic-field-sensitive component is couplable to the electronic device at a location on the electronic device expected to generate vibrations.

3. The testing system of claim 2, wherein:
the electronic device comprises a printed circuit board; and
the location on the electronic device includes a component location on the printed circuit board where a component is to be mounted on the printed circuit board or on the component mounted at the component location.

4. The testing system of claim 3, wherein the component includes a capacitor.

5. The testing system of claim 1, wherein the magnetic-field-sensitive component is adhesively couplable to the electronic device.

6. The testing system of claim 5, wherein the magnetic-field-sensitive component is adhesively couplable to the electronic device using a detachable adhesive enabling the magnetic-field-sensitive component to be detached from a first location on the electronic device and reattached to a second location on the electronic device.

7. The testing system of claim 1, wherein the magnetic-field-sensitive component includes a permanent magnet.

8. The testing system of claim 1, further comprising:
an electric current source, the electric current source configured to supply the alternating electric current at selectable current frequencies, and wherein differing current frequencies of the selectable current frequencies results in differing frequencies of the variable-frequency magnetic field.

9. The testing system of claim 1, further comprising:
a vibration monitoring sensor configured to detect vibration of the electronic device having the magnetic-field-sensitive component in response to the variable-frequency magnetic field.

10. The testing system of claim 9, wherein the vibration monitoring sensor includes at least one of a microphone or an optical sensor.

11. A method comprising:
securing, mechanically, an electronic device;
positioning a magnetic coil proximate to the electronic device, the magnetic coil configured to generate a variable frequency magnetic field in response to an alternating electric current;
coupling a magnetic-field-sensitive component to the electronic device;
applying the alternating electric current at the magnetic coil sufficient to cause a vibration of the electronic device in response to a magnetic force exerted by the variable frequency magnetic field at the magnetic-field-sensitive component; and
monitoring vibrations of the electronic device at one or more frequencies of the alternating electric current.

12. The method of claim 11, further comprising:
adhesively coupling the magnetic-field-sensitive component to the electronic device.
